(19) United States
(12) Patent Application Publication
(10) Pub. No.: US 2009/0152666 A1
(43) Pub. Date: Jun. 18, 2009

(54) THERMOELECTRIC SEMICONDUCTOR DEVICE

(76) Inventor: Chin-Kuang Luo, Taichung City (TW)

Correspondence Address: TROP, PRUNER & HU, P.C., 1616 S. VOSS ROAD, SUITE 750, HOUSTON, TX, 77057-2631, US

(21) Appl. No.: 12/358,276

(22) Filed: Jan. 23, 2009

Related U.S. Application Data
(63) Continuation-in-part of application No. 11/529,833, filed on Sep. 29, 2006.

(30) Foreign Application Priority Data
Mar. 20, 2008 (TW) 097109853

(51) Int. Cl. H01L 27/16

(52) U.S. Cl. 257/470; 257/E27.008

(57) ABSTRACT

A thermoelectric semiconductor device includes a plurality of alternating P-type and N-type semiconductor elements disposed between first and second ceramic layers, first conductor elements attached to the first ceramic layer and interconnecting cold junctions of the P-type and N-type semiconductor elements, and second conductor elements attached to the second ceramic layer and interconnecting hot junctions of the P-type and N-type semiconductor elements. A thermal insulation material made from ammonium phosphate is filled in gaps between the first and second ceramic layers and the P-type and N-type semiconductor elements so that the temperature difference between the hot and cold junctions can be maximized

### CROSS-REFERENCE TO RELATED APPLICATION

This application is a continuation-in-part (CIP) of U.S. patent application Ser. No. 11/529833, filed on Sep. 29, 2006, the entire disclosure of which is incorporated herein by reference.

### BACKGROUND OF THE INVENTION

1. Field of the Invention

This invention relates to a thermoelectric semiconductor device, more particularly to a thermoelectric semiconductor device including a thermal insulation material made from ammonium phosphate.

2. Description of the Related Art

Referring to FIG. 1, a conventional thermoelectric semiconductor device includes a P-type semiconductor 11, a N-type semiconductor 12, and conductive metals 13 that interconnect in series the P-type and N-type semiconductors 11, 12 so as to form a closed circuit loop. When the P-type and N-type semiconductors have different temperatures at two junctions thereof, which respective force (Seebeck effect) is generated in the closed circuit loop. The higher the temperature difference is, the higher will be the electromotive force. However, since the temperature difference between the junctions is prone to decrease due to heat loss by convection and radiation through the gap between the P-type and N-type semiconductors 11, 12, thermoelectric effect tends to be reduced, thereby lowering the efficiency of electricity generation.

In addition, the P-type and N-type semiconductors 11, 12 are typically formed by a high pressure process of pressing a metal powder, followed by cutting into pellets. The pellets of the P-type and N-type semiconductors 11, 12 are subsequently welded to the conductive metals 13 using a Sn-based solder. Since the Sn-based solder has a relatively low melting temperature (about 200° C.), when the thermoelectric semiconductor device is subjected to a high temperature environment, the P-type and N-type semiconductors 11, 12 are likely to separate and even disintegrate.

### SUMMARY OF THE INVENTION

Therefore, an object of the present invention is to provide a thermoelectric semiconductor device that can overcome the aforesaid drawbacks associated with the prior art.

According to the present invention, a thermoelectric semiconductor device comprises: first and second ceramic layers having inner surfaces facing each other; a plurality of alternating P-type and N-type semiconductor elements disposed between the inner surfaces of the first and second ceramic layers and electrically interconnected in series, each of the P-type and N-type semiconductor elements having a cold junction proximate to the first ceramic layer, and a hot junction proximate to the second ceramic layer; first conductor elements attached to the inner surface of the first ceramic layer in a spaced apart relationship, each of the first conductor elements interconnecting electrically the cold junction of one of the P-type semiconductor elements and the cold junction of one of the N-type semiconductor elements; second conductor elements attached to the inner surface of the second ceramic layer in a spaced apart relationship, each of the second conductor elements interconnecting electrically the hot junction of one of the P-type semiconductor elements and the hot junction of one of the N-type semiconductor elements; and a thermal insulation material filled in gaps between the first and second ceramic layers and between the N-type and P-type semiconductor elements. The thermal insulation material is made from ammonium phosphate.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic diagram of a conventional thermoelectric semiconductor device; and

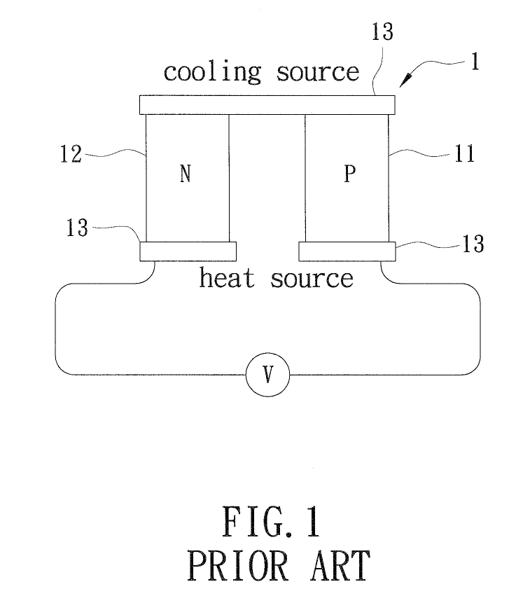

FIG. 2 is a schematic diagram of the preferred embodiment of a thermoelectric semiconductor device according to this invention.

### DETAILED DESCRIPTION OF THE PREFERRED EMBODIMENT

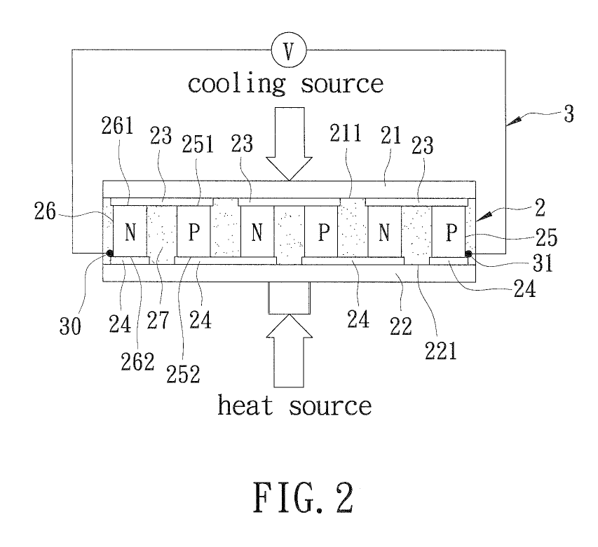

Referring to FIG. 2, there is shown a thermoelectric semiconductor device 2 according to a preferred embodiment of this invention, which can be used in combination with a natural heat source and a natural cooling source. The thermoelectric semiconductor device 2 includes first and second ceramic layers 21, 22, a plurality of P-type and N-type semiconductor elements 25, 26, first and second conductor elements 23, 24, and a thermal insulation material 27.

The first and second ceramic layers 21, 22 are spaced apart from each other and have inner surfaces 211, 221 facing each other.

The plurality of alternating P-type and N-type semiconductor elements 25, 26 are disposed between the inner surfaces 211, 221 of the first and second ceramic layers 21, 22 and are electrically interconnected in series through the first and second conductor elements 23, 24. Each of the P-type and N-type semiconductor elements 25, 26 has a cold junction 251, 261 proximate to the first ceramic layer 21, and a hot junction 252, 262 proximate to the second ceramic layer 22.

The first conductor elements 23 are attached to the inner surface 211 of the first ceramic layer 21 in a spaced apart relationship. Each of the first conductor elements 23 interconnects electrically the cold junction 251 of one of the P-type semiconductor elements 25 and the cold junction 251 of one of the N-type semiconductor elements 26. The second conductor elements 24 are attached to the inner surface 221 of the second ceramic layer 22 in a spaced apart relationship. Each of the second conductor elements 24 interconnects electrically the hot junction 252 of one of the P-type semiconductor elements 25 and the hot junction 262 of one of the N-type semiconductor elements 26.

The thermal insulation material 27 is injected between the first and second ceramic layers 21, 22. Though a centrifugal treatment, the thermal insulation material 27 spreads uniformly and fills completely the gaps between the P-type and N-type semiconductor elements 25, 26 and between the first and second ceramic layers 21, 22. The thermal insulation material 27 is made from ammonium phosphate.

The first ceramic layer 21 may be used to contact a natural cooling source, such as river, sea water, underground water, reservoir water, etc. The second ceramic layer 22 may be used to contact a natural heat source, such as stack or exhaust gases produced from factories, terrestrial heat, hot spring, etc.

In this embodiment, the P-type and N-type semiconductor elements 25, 26 are made by compacting and heating Sb and Bi powders, followed by cutting the resulting product into pellets so as to obtain the P-type and N-type semiconductor elements 25, 26. Subsequently, the P-type and N-type semiconductor elements 25, 26 are bonded to the first and second conductor elements 23, 24 using a copper solder. In this embodiment, the first and second conductor elements 23, 24 are made from copper foils.

In use, a circuit member 3 is connected to two terminal leads 30, 31 which are connected respectively to the hot junctions 252, 262 of an outermost one of the P-type semiconductor elements 25 and an outermost one of the N-type semiconductor elements 26, thereby forming a closed circuit loop. When the first and second ceramic layers 21, 22 respectively contact the cooling source and the heat source, a temperature difference is created between the cold junctions 251, 261 of the P-type and N-type semiconductor elements 25, 26 and the hot junctions 252, 262 of the P-type and N-type semiconductor elements 25, 26, thereby generating a current flow in the closed circuit loop.

Since the thermal insulation material 27 made from ammonium phosphate fills the gaps between the first and second ceramic layers 21, 22 and between the P-type and N-type semiconductor elements 25, 26, heat loss via heat convection and radiation through the gaps upon heat transfer from the hot junctions 252, 262 to the cold junctions 251, 261 can be alleviated. Thus, the temperature difference between the cold junctions 251, 261 and the hot junctions 252, 262 can be maximized, and thermoelectric efficiency of the thermoelectric semiconductor device 2 can be enhanced.

In addition, since the copper solder used to bond the P-type and N-type semiconductor elements 25, 26 to the first and second conductor elements 23, 24 is resistant to temperatures higher than 500° C., the thermoelectric semiconductor device 2 has a strong structural strength that can be operated under a relatively high temperature without disintegration.

With the invention thus explained, it is apparent that various modifications and variations can be made without departing from the spirit of the present invention. It is therefore intended that the invention be limited only as recited in the appended claims.

What is claimed is:

1. A thermoelectric semiconductor device comprising:
first and second ceramic layers having inner surfaces facing each other;
a plurality of alternating P-type and N-type semiconductor elements disposed between said inner surfaces of said first and second ceramic layers and electrically interconnected in series, each of said P-type and N-type semiconductor elements having a cold junction proximate to said first ceramic layer, and a hot junction proximate to said second ceramic layer;
first conductor elements attached to said inner surface of said first ceramic layer in a spaced apart relationship, each of said first conductor elements interconnecting electrically said cold junction of one of said P-type semiconductor elements and said cold junction of one of said N-type semiconductor elements;
second conductor elements attached to said inner surface of said second ceramic layer in a spaced apart relationship, each of said second conductor elements interconnecting electrically said hot junction of one of said P-type semiconductor elements and said hot junction of one of said N-type semiconductor elements; and
a thermal insulation material filled in gaps between said first and second ceramic layers and between said N-type and P-type semiconductor elements, said thermal insulation material being made from ammonium phosphate.

2. A thermoelectric semiconductor device of claim 1, wherein said P-type and N-type semiconductor elements are made from a material that includes powdered Sb and Bi.

3. A thermoelectric semiconductor device of claim 1, further comprising a copper solder to bond said P-type and N-type semiconductor elements to said first and second conductor elements, said first and second conductor elements being made from copper foils.
